(19) United States
(12) Patent Application Publication
(10) Pub. No.: US 2025/0275052 A1
(43) Pub. Date: Aug. 28, 2025

(54) BEAM TUBE AND LAYOUT FOR LINEAR ACCELERATOR

(71) Applicant: Applied Materials, Inc., Santa Clara, CA (US)

(72) Inventors: Aaron P. WEBB, Austin, TX (US); Jason M. SCHALLER, Austin, TX (US); William Herron PARK, JR., Marblehead, MA (US)

(73) Assignee: Applied Materials, Inc., Santa Clara, CA (US)

(21) Appl. No.: 18/589,202

(22) Filed: Feb. 27, 2024

(51) Int. Cl. H05H 7/04; H01J 37/08; H01J 37/317; H05H 9/00

(52) U.S. Cl. CPC H05H 7/04; H01J 37/08; H05H 9/00; H01J 37/3171; H01J 2237/04732; H05H 2007/041

(57) ABSTRACT

An ion implantation system including an ion source for generating an ion beam, an end station for holding a substrate to be implanted by the ion beam, and a linear accelerator disposed between the ion source and the end station and adapted to accelerate the ion beam, the linear accelerator including a beam tube for transmitting the ion beam, the beam tube having at least five adjoining sidewalls, at least one resonator coupled to the beam tube, and at least one turbomolecular pump coupled to the beam tube, wherein at least one of the at least five adjoining sidewalls of the beam tube has an opening formed therein for providing access to an interior of the beam tube.

### FIELD OF THE DISCLOSURE

This disclosure relates generally to the field of ion implantation apparatus and relates more particularly to linear accelerators for ion implantation apparatus.

### BACKGROUND OF THE DISCLOSURE

Ion implantation is a process of introducing dopants or impurities into a substrate via ionic bombardment. A typical ion implantation system includes an ion source and a series of beam-line components. The ion source may include a chamber where ions are generated for subsequent transmission through the beam-line components toward a substrate. One type of ion implantation system suitable for generating ion beams of medium and high energies employs a linear accelerator. A linear accelerator includes a beam tube for transmitting an ion beam, and a series of resonators containing AC or RF electrodes arranged around the beam tube for accelerating the ion beam to increasingly higher energies along the succession of resonators.

Conventionally, a beam tube of a linear accelerator has four adjoining sidewalls defining a square or diamond-shape when viewed end-on. A plurality of resonators are mounted to the sidewalls along the length of the beam tube. Additionally, a plurality of turbomolecular pumps may be mounted to the sidewalls for establishing a vacuum within the beam tube. Still further, a plurality of quadrupole magnets may be mounted to the sidewalls for focusing and steering an ion beam within the beam tube. Various other components, chases, etc. may also be mounted to the sidewalls. With all of the aforementioned components mounted to the beam tube, relatively little space is left on the sidewalls for providing access to an interior of the beam tube to facilitate service and maintenance of internal components (e.g., electrodes, coils, etc.). As a result, accessing the interior of the beam tube and performing service and maintenance is often difficult, cumbersome, and time-consuming. Moreover, linear accelerators having the above-described configuration have large footprints, owing to long beam tubes, and thus take up a great deal of valuable space within a manufacturing facility.

With respect to these and other considerations, the present disclosure is provided.

### BRIEF SUMMARY

This Summary is provided to introduce a selection of concepts in a simplified form. This Summary is not intended to identify key features or essential features of the claimed subject matter, nor is this Summary intended as an aid in determining the scope of the claimed subject matter.

According to an embodiment of the present disclosure, an ion implantation system is provided, the ion implantation system including an ion source for generating an ion beam, an end station for holding a substrate to be implanted by the ion beam, and a linear accelerator disposed between the ion source and the end station and adapted to accelerate the ion beam, the linear accelerator including a beam tube for transmitting the ion beam, the beam tube having at least five adjoining sidewalls, at least one resonator coupled to the beam tube, and at least one turbomolecular pump coupled to the beam tube, wherein at least one of the at least five adjoining sidewalls of the beam tube has an opening formed therein for providing access to an interior of the beam tube.

According to another embodiment of the present disclosure, an ion implantation system is provided, the ion implantation system including an ion source for generating an ion beam, an end station for holding a substrate to be implanted by the ion beam, and a linear accelerator disposed between the ion source and the end station and adapted to accelerate the ion beam, the linear accelerator including a beam tube for transmitting the ion beam, the beam tube having six adjoining sidewalls defining a hexagon when the beam tube is viewed end-on, at least one resonator coupled to the beam tube, and at least one turbomolecular pump coupled to the beam tube, wherein at least one of the at least five adjoining sidewalls of the beam tube has an opening formed therein for providing access to an interior of the beam tube.

According to another embodiment of the present disclosure, a beam tube for a linear accelerator of an ion implantation system is provided, the beam tube including at least five adjoining sidewalls.

### BRIEF DESCRIPTION OF THE DRAWINGS

The accompanying drawings illustrate exemplary approaches of the present disclosure, including the practical application of the principles thereof, as follows:

FIG. 1 is a schematic view illustrating an ion implantation system in accordance with an embodiment of the present disclosure;

FIG. 2A is an end-on view illustrating a liner accelerator in accordance with an embodiment of the present disclosure;

FIG. 2B is a left-side perspective view illustrating the linear accelerator shown in FIG. 2A;

FIG. 2C is a right-side perspective view illustrating the linear accelerator shown in FIG. 2A;

FIG. 3 is a left-side perspective view illustrating the linear accelerator shown in FIG. 2A with several quadrupole magnets removed to provide access to an interior of a beam tube;

FIG. 4 is a right-side perspective view illustrating the linear accelerator shown in FIG. 2A with a plurality of access doors in a pump chase for providing access to an interior of the beam tube.

The drawings are not necessarily to scale. The drawings are merely representations, not intended to portray specific parameters of the disclosure. The drawings are intended to depict exemplary embodiments of the disclosure, and thus are not to be considered as limiting in scope. In the drawings, like numbering represents like elements.

### DETAILED DESCRIPTION

Systems and apparatus in accordance with the present disclosure will now be described more fully hereinafter with reference to the accompanying drawings, where embodiments of the systems and apparatus are shown. The systems and apparatus may be embodied in many different forms and are not to be construed as being limited to the embodiments set forth herein. Instead, these embodiments are provided so this disclosure will be thorough and complete, and will fully convey the scope of the systems and apparatus to those skilled in the art.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

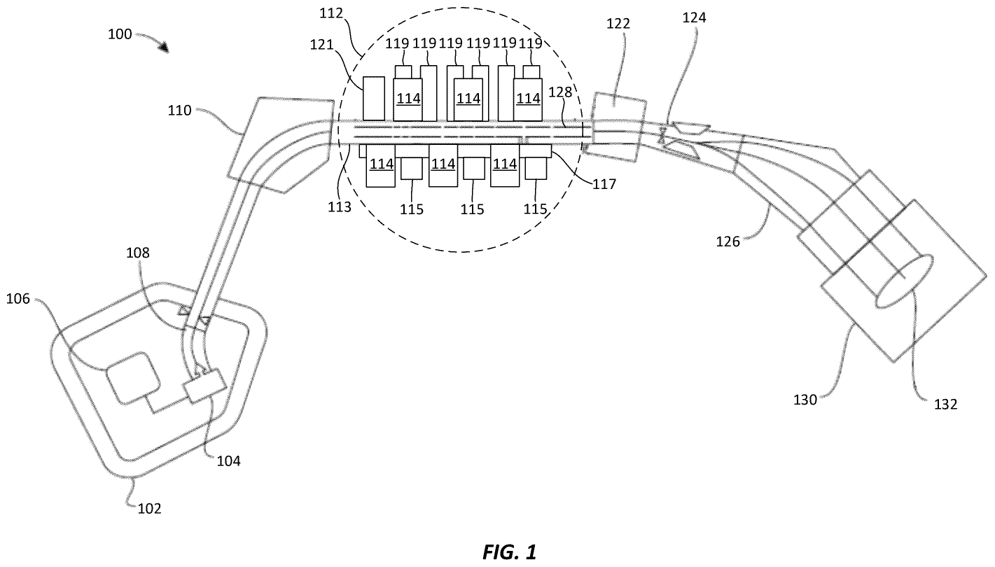

Referring to FIG. 1, a schematic view illustrating an ion implantation system 100 according to embodiments of the present disclosure is shown. The ion implantation system 100 may represent a beamline ion implanter, with some elements omitted for clarity of explanation. The ion implantation system 100 may include an ion source 104 and a gas box 106 positioned within a terminal 102. The ion source 104 may include extraction components and filters (not shown) configured to generate an ion beam 108 at a first energy. Examples of suitable ion energies for the first ion energy range from 5 keV to 100 keV. The present disclosure is not limited in this regard. To form a high energy ion beam, the ion implantation system 100 may include various additional components for accelerating the ion beam 108 as further discussed below.

The ion implantation system 100 may include an analyzer 110 adapted to receive and analyze the ion beam 108. In some embodiments, the analyzer 110 may receive the ion beam 108 with an energy imparted by extraction optics located at the ion source 104, where the ion energy is in the range of 100 keV or below, and, in particular, 80 keV or below. In other embodiments, the analyzer 110 may receive the ion beam 108 accelerated by a DC accelerator column to higher energies such as 200 keV, 250 keV, 300 keV, 400 keV, or 500 keV. The embodiments are not limited in this context. The ion implantation system 100 may also include a linear accelerator 112, disposed downstream of the analyzer 110. The linear accelerator 112 may include a beam tube 113 through which the ion beam 108 is transmitted, and a plurality of accelerator stages, arranged in series, as represented by resonators 114 coupled to the beam tube 113. The resonators 114 may be powered by respective, dedicated RF sources (not separately shown). The linear accelerator 112 may further include a plurality of turbomolecular pumps 115 coupled to the beam tube 113 via a pump chase 117 for establishing and maintaining a vacuum (or near vacuum) within the beam tube 113. The linear accelerator 112 may further include a plurality of quadrupole magnets 119 coupled to the beam tube 113 for focusing the ion beam 108.

A given stage of the linear accelerator 112 may be driven by a given resonator, generating an AC voltage signal in the MHz range (RF range), where the AC voltage signal generates an AC field at an electrode of the given stage. The AC field acts to accelerate the ion beam 108, wherein the ion beam 108 may be delivered to the stages in packets as a bunched ion beam. The linear accelerator 112 may further include one or more bunchers 121 coupled to the beam tube 113 upstream of the first resonator 114. The buncher 121 may be configured to receive a continuous ion beam and generate a bunched ion beam by action of an RF resonator within the buncher 121. The resonators 114 may operate to accelerate the ion beam 108 to higher energies in stages. Thus, the buncher 121 may be considered a first accelerator stage, differing from downstream resonators 114 in that the ion beam 108 is received as a continuous ion beam in the buncher 121.

In various embodiments, the ion implantation system 100 may include additional components, such as a filter magnet 122, a scanner 124, and collimator 126, where the general functions of the filter magnet 122, scanner 124, and collimator 126 are well known and will not be described herein in further detail. As such, a high energy ion beam, represented by high energy ion beam 128, after acceleration by the linear accelerator 112, may be delivered to an end station 130 of the ion implantation system 100 for processing of a substrate 132.

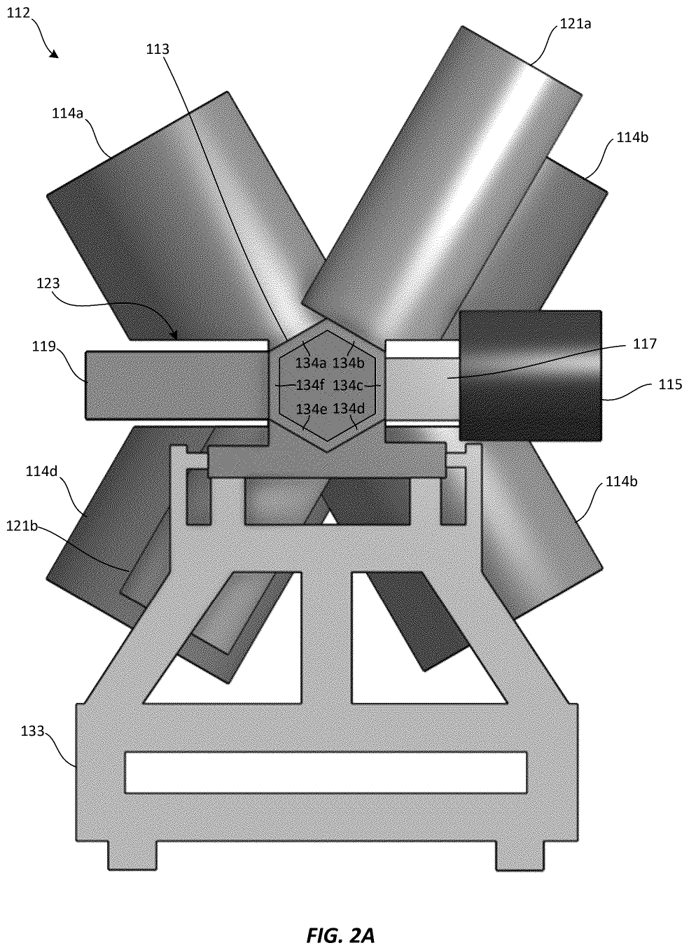

Referring to FIGS. 2A-2C, an end-on view, a left-side perspective view, and a right-side perspective view illustrating the linear accelerator 112 of the present disclosure in isolation are shown, respectively. These views have been simplified for the purpose of emphasizing certain features of the linear accelerator 112. Those of skill in the art will appreciate that various components and features common to linear accelerators have been omitted from the views shown in FIGS. 2A-C for the sake of clarity.

As shown in FIGS. 2A-C, the beam tube 113 of the linear accelerator 112 may be suspended on a frame or stand 133. The linear accelerator 112 may be hexagonal in shape (i.e., when viewed end-on), having six adjoining sidewalls, including a first sidewall 134a, a second sidewall 134b, a third sidewall 134c, a fourth sidewall 134d, a fifth sidewall 134e, and a sixth sidewall 134f. This configuration is to be contrasted with conventional beam tubes, which are square or diamond in shape (i.e., when viewed end-on), having four adjoining sidewalls. Thus, the beam tube 113 of the present disclosure provides two additional sidewalls/mounting surfaces for accommodating components of the linear accelerator 112, as well as for providing access to an interior of the linear accelerator 112 (as further described below), relative to conventional, four-sided beam tubes. Alternative embodiments of the present disclosure are contemplated wherein the beam tube 113 may be implemented with 5 sidewalls or more than 6 sidewalls. The present disclosure is not limited in this regard.

In a non-limiting embodiment, and as shown in FIGS. 2A-C, a first plurality of resonators 114a may be mounted to the first sidewall 134a of the beam tube 113 in linear series along a length of the beam tube 113. A second plurality of resonators 114b may be mounted to the second sidewall 134b of the beam tube 113 in linear series along a length of the beam tube 113. A pump chase 117 may be mounted to the third sidewall 134c of the beam tube 113, and a plurality of turbomolecular pumps 115 may be mounted to the pump chase 117 in linear series along a length of the pump chase 117. A third plurality of resonators 114c may be mounted to the fourth sidewall 134d of the beam tube 113 in linear series along a length of the beam tube 113. A fourth plurality of resonators 114d may be mounted to the fifth sidewall 134e of the beam tube 113 in linear series along a length of the beam tube 113. A plurality of quadrupole magnets 119 may be mounted to the sixth sidewall 134f of the beam tube 113 in linear series along a length of the beam tube 113. In addition to the aforementioned components, a first buncher 121a may be coupled to the second sidewall 134b of the beam tube 113, upstream of the second plurality of resonators 114b, and a second buncher 121b may be coupled to the fifth sidewall 134e of the beam tube 113, upstream of the fourth plurality of resonators 114d. The above-described arrangement is not intended to be limiting, and the resonators 114a-d, pump chase 117, turbomolecular pumps 115, quadrupole magnets 119, and bunchers 121a-b may be mounted to the sidewalls 134a-f of the beam tube 113 in any practical arrangement without limitation.

In various embodiments, and as best shown in FIG. 2A, one or more of the first, second, third, and fourth pluralities of resonators 114a-d, and/or one or both of the bunchers 121a-b, may be specially shaped to facilitate cooperative arrangement/mounting around the beam tube 113. For example, the resonator 114a may be generally cylindrical in shape, but may have a notch 123 formed in a base portion thereof, allowing the resonator 114a to be mounted to the sidewall 134a while providing clearance for the quadrupole magnets 119. The other resonators 114b-d and the bunchers 121a-b may be similarly shaped. More generally, the resonators 114a-d and the bunchers a-b may be smaller at the junctures of such components with the beam tube 113 relative to portions of such components more distal from the beam tube 113. In this context, “smaller” shall be defined to mean smaller in cross-sectional size or diameter.

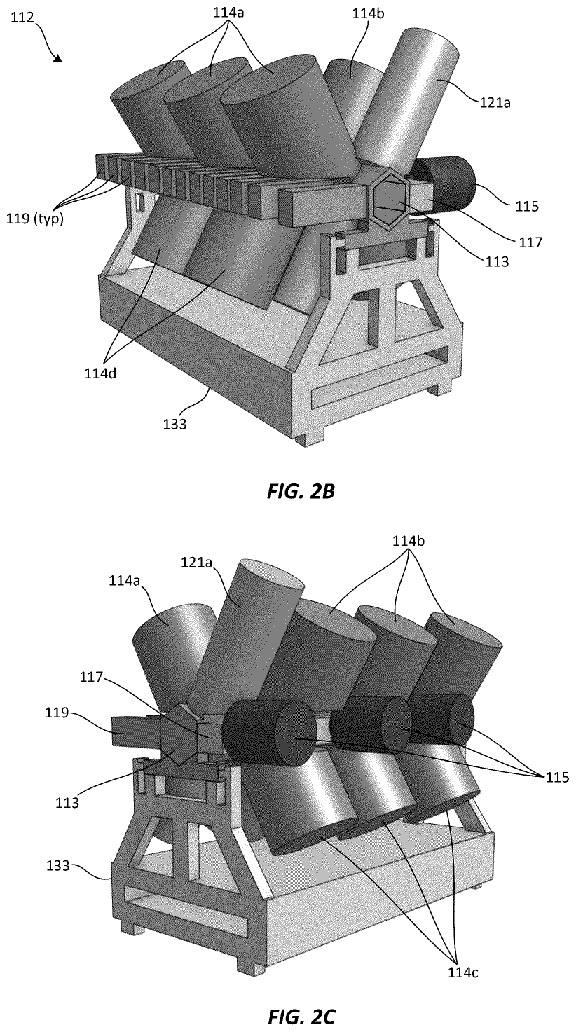

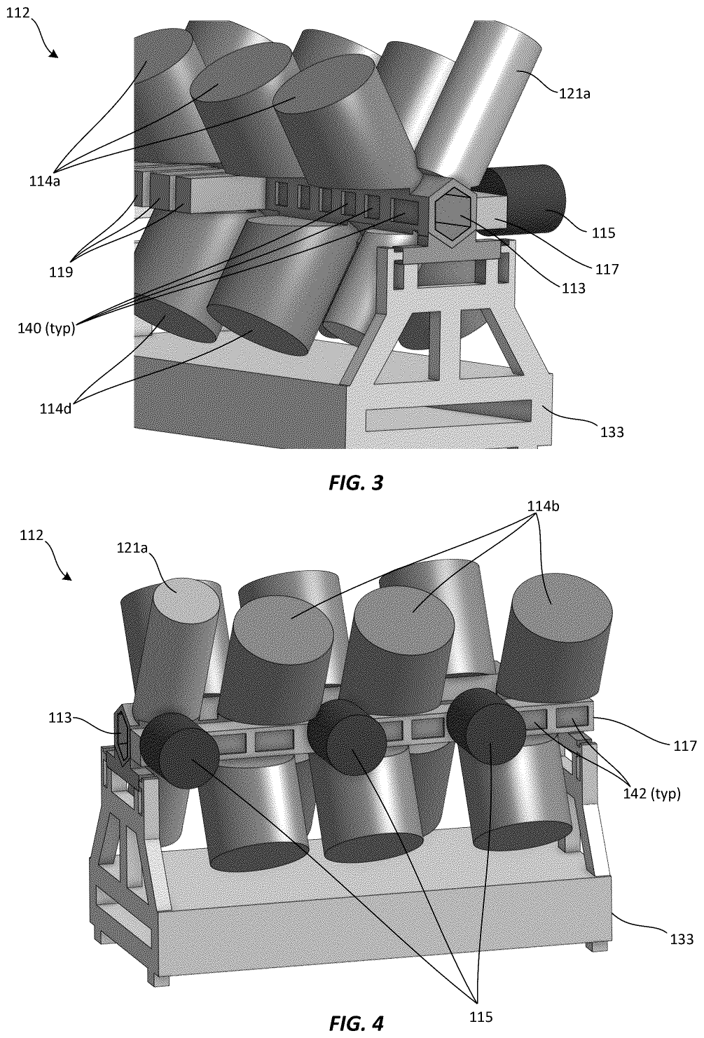

Referring to FIG. 3, an interior of the beam tube 113 may be accessed by removing one or more of the quadrupole magnets 119. For example, when one or more of the quadrupole magnets 119 is removed, corresponding openings 140 in the sixth sidewall 134f of the beam tube 113 may be exposed, thus providing access to the interior of the beam tube 113. Additionally or alternatively, and with reference to FIG. 4, the pump chase 117 may include one or more openings with removable/closable access doors 142 located between and/or adjacent the turbomolecular pumps 115 for providing access to the interior of the beam tube 113 via the pump chase 117. Thus, the openings 140 and/or the access doors 142, which may be located on opposite lateral sides of the beam tube 113, may provide convenient and expeditious access to the interior of the beam tube 113, such as may be necessary for performing repairs or maintenance, adjusting internal components, etc.

In view of the foregoing, at least the following advantages are achieved by the embodiments disclosed herein. As a first advantage, the hexagonal beam tube 113 of the present disclosure provides greater surface area over a given length of the beam tube 113 relative to traditional, four-sided beam tubes. Thus, the beam tube 113 may accommodate a greater number of components (e.g., resonators, bunchers, turbomolecular pumps, quadrupole magnets, etc.) over a given length and/or may be implemented with a smaller overall footprint relative to traditional, four-sided beam tubes. As a second advantage, the increased surface area of the hexagonal beam tube 113 of the present disclosure provides more space for allowing convenient and expeditious access to an interior of the beam tube 113.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

1. An ion implantation system comprising:
an ion source for generating an ion beam;
an end station for holding a substrate to be implanted by the ion beam; and
a linear accelerator disposed between the ion source and the end station and adapted to accelerate the ion beam, the linear accelerator comprising:
a beam tube for transmitting the ion beam, the beam tube having at least five adjoining sidewalls;
at least one resonator coupled to the beam tube; and
at least one turbomolecular pump coupled to the beam tube;
wherein at least one of the at least five adjoining sidewalls of the beam tube has an opening formed therein for providing access to an interior of the beam tube.

2. The ion implantation system of claim 1, further comprising at least one quadrupole magnet coupled to the beam tube.

3. The ion implantation system of claim 1, further comprising at least one buncher coupled to the beam tube.

4. The ion implantation system of claim 1, wherein the at least one turbomolecular pump comprises a plurality of turbomolecular pumps coupled to the beam tube via a pump chase coupled to one of the at least five adjoining sidewalls of the beam tube.

5. The ion implantation system of claim 1, wherein the at least five adjoining sidewalls comprises six adjoining sidewalls defining a hexagon when the beam tube is viewed end-on.

6. The ion implantation system of claim 5, wherein the at least one resonator comprises a first plurality of resonators, a second plurality of resonators, a third plurality of resonators, and a fourth plurality of resonators, and wherein the at least one turbomolecular pump comprises a plurality of turbomolecular pumps, the ion implantation system further comprising a plurality of quadrupole magnets coupled to the beam tube via a pump chase, wherein:
the first plurality of resonators is coupled to a first of the six adjoining sidewalls;
the second plurality of resonators is coupled to a second of the six adjoining sidewalls;
the pump chase is coupled to a third of the six adjoining sidewalls;
the third plurality of resonators is coupled to a fourth of the six adjoining sidewalls;
the fourth plurality of resonators is coupled to a fifth of the six adjoining sidewalls; and
the plurality of quadrupole magnets is coupled to a sixth of the six adjoining sidewalls.

7. The ion implantation system of claim 6, further comprising at least one buncher coupled to at least one of the first, second, fourth, and fifth of the six adjoining sidewalls.

8. The ion implantation system of claim 6, wherein the pump chase includes a plurality of openings formed therein for providing access to the interior of the beam tube, the plurality of openings in the pump chase being located between the turbomolecular pumps.

9. The ion implantation system of claim 6, wherein at least one of the quadrupole magnets can be removed to provide access to the interior of the beam tube.

10. The ion implantation system of claim 1, wherein the at least one resonator is smaller at a juncture of the at least one resonator with the beam tube relative to portions of the at least one resonator more distal from the beam tube.

11. An ion implantation system comprising:
an ion source for generating an ion beam;
an end station for holding a substrate to be implanted by the ion beam; and
a linear accelerator disposed between the ion source and the end station and adapted to accelerate the ion beam, the linear accelerator comprising:
a beam tube for transmitting the ion beam, the beam tube having six adjoining sidewalls defining a hexagon when the beam tube is viewed end-on;
at least one resonator coupled to the beam tube; and
at least one turbomolecular pump coupled to the beam tube;
wherein at least one of the six adjoining sidewalls of the beam tube has an opening formed therein for providing access to an interior of the beam tube.

12. The ion implantation system of claim 11, further comprising at least one quadrupole magnet coupled to the beam tube.

13. The ion implantation system of claim 11, further comprising at least one buncher coupled to the beam tube.

14. The ion implantation system of claim 11, wherein the at least one turbomolecular pump comprises a plurality of turbomolecular pumps coupled to the beam tube via a pump chase coupled to one of the six adjoining sidewalls of the beam tube.

15. The ion implantation system of claim 11, wherein the at least one resonator comprises a first plurality of resonators, a second plurality of resonators, a third plurality of resonators, and a fourth plurality of resonators, and wherein the at least one turbomolecular pump comprises a plurality of turbomolecular pumps, the ion implantation system further comprising a plurality of quadrupole magnets coupled to the beam tube via a pump chase, wherein:
the first plurality of resonators is coupled to a first of the six adjoining sidewalls;
the second plurality of resonators is coupled to a second of the six adjoining sidewalls;
the pump chase is coupled to a third of the six adjoining sidewalls;
the third plurality of resonators is coupled to a fourth of the six adjoining sidewalls;
the fourth plurality of resonators is coupled to a fifth of the six adjoining sidewalls; and
the plurality of quadrupole magnets is coupled to a sixth of the six adjoining sidewalls.

16. The ion implantation system of claim 15, further comprising at least one buncher coupled to at least one of the first, second, fourth, and fifth of the six adjoining sidewalls.

17. The ion implantation system of claim 15, wherein the pump chase includes a plurality of openings formed therein for providing access to the interior of the beam tube, the plurality of openings in the pump chase being located between the turbomolecular pumps.

18. The ion implantation system of claim 15, wherein at least one of the quadrupole magnets can be removed to provide access to the interior of the beam tube.

19. The ion implantation system of claim 11, wherein the at least one resonator is smaller at a juncture of the at least one resonator with the beam tube relative to portions of the at least one resonator more distal from the beam tube.

20. A beam tube for a linear accelerator of an ion implantation system, the beam tube comprising at least five adjoining sidewalls.
